(19) United States
(12) Patent Application Publication
(10) Pub. No.: US 2012/0121108 A1
(43) Pub. Date: May 17, 2012

(54) COOPERATIVE VOICE DIALOG AND BUSINESS LOGIC INTERPRETERS FOR A VOICE-ENABLED SOFTWARE APPLICATION

(76) Inventors: Dennis Doubleday, Pittsburgh, PA (US); Eric Stark, Bethel Park, PA (US); Arthur McNair, Pittsburgh, PA (US); TIm Lesher, Sewickley, PA (US); Mark Koenig, Pittsburgh, PA (US); Ed Stoll, Monroeville, PA (US); Mike Ressler, Pittsburgh, PA (US); Swathi Voruganti, Franklin, TN (US)

(21) Appl. No.: 12/947,014

(22) Filed: Nov. 16, 2010

(51) Int. Cl. H03G 3/20

(52) U.S. Cl. 381/110

(57) ABSTRACT

Embodiments of the invention address the deficiencies of the prior art by providing a method, apparatus, and program product to cooperatively mediate between voice-enabled operations and business logic. The method comprises receiving XML data and generating at least one object from the XML data. The method further comprises, in response to determining that the at least one object has been called, implementing an operation defined by a portion of the object.

### FIELD OF THE INVENTION

Embodiments of the invention relate to voice driven systems, and in particular a voice driven system that includes cooperating voice dialog and business logic interpreters.

### BACKGROUND OF THE INVENTION

In general, voice-enabled software is computationally intensive. For example, voice-enabled software often requires consideration for voice-enabled operations (e.g., capturing and converting speech input from a user and/or providing speech output to a user) that operate pursuant to a particular flow of dialog. It also often requires consideration for other logical operations, such as determinations of the truth of a particular condition.

Operations in voice-enabled software are typically implemented in a serial manner, that is, operations be completed as they are encountered. For example, VoiceXML (VXML) has been implemented in some voice-enabled software to provide speech synthesis and speech recognition as well as the business logic for voice-enabled software. VXML for voice-enabled software contains both the control flow of as well as the business logic in the XML itself. However, this serial flow prevents optimization of the voice-enabled software. Specifically, VXML typically requires that operations be completed as they are encountered, thus leaving no capability for optimization to improve the operation of the voice-enabled software.

### SUMMARY OF THE INVENTION

Embodiments of the invention address the deficiencies of the prior art by providing a method, apparatus, and program product to cooperatively mediate between voice-enabled operations and business logic. The method comprises receiving XML data and generating at least one object from the XML data. The method further comprises, in response to determining that the at least one object has been called, implementing an operation defined by a portion of the object.

Embodiments of the invention provide for the creation of voice dialog objects that can be subsequently called during a dialog flow. In this manner, embodiments of the invention allow for the mediation between voice-enabled operations and business logic, allowing pre-processing of some operations and/or parallelizing of those operations. Thus, the efficiency and operation of the voice-enabled application can be increased without sacrificing operational capability. These and other advantages will be apparent in light of the following figures and detailed description.

### BRIEF DESCRIPTION OF THE DRAWINGS

The accompanying drawings, which are incorporated in and constitute a part of this specification, illustrate embodiments of the invention and, together with a general description of the invention given above and the detailed description of the embodiments given below, serve to explain the principles of the invention.

FIG. 1 is a diagrammatic illustration of a voice-enabled system that includes an voice client server and a mobile system consistent with embodiments of the invention;

FIG. 2 is a diagrammatic illustration of hardware and software components of the voice client server of FIG. 1;

FIG. 3 is an illustration of the mobile system of FIG. 1 further illustrating a mobile device and headset thereof;

FIG. 4 is a diagrammatic illustration of hardware and software components of the mobile device and headset of FIG. 3;

FIG. 5 is a diagrammatic illustration of a plurality of software modules that may be included in the voice client server of FIG. 1;

FIG. 6 is a diagrammatic illustration of a plurality of software modules that may be included in the mobile system of FIG. 1;

FIG. 7 is a diagrammatic illustration of a graphical representation of a first voice dialog that may be implemented in the voice-enabled system of FIG. 1;

FIG. 8 is a diagrammatic illustration of a graphical representation of a second voice dialog that may be implemented in the voice-enabled system of FIG. 1;

FIG. 9 is a flowchart illustrating a sequence of operations for the configuration of a voice application of the voice-enabled system of FIG. 1;

FIG. 10 is a flowchart illustrating a sequence of operations for a VoiceArtisan application of the voice-enabled system of FIG. 1 to respond to a call for a voice dialog; and

FIG. 11 is a flowchart illustrating a sequence of operations for a VoiceArtisan application of the voice-enabled system of FIG. 1 to create a voice dialog object corresponding to a voice dialog.

It should be understood that the appended drawings are not necessarily to scale, presenting a somewhat simplified representation of various features illustrative of the basic principles of embodiments of the invention. The specific design features of embodiments of the invention as disclosed herein, including, for example, specific dimensions, orientations, locations, and shapes of various illustrated components, as well as specific sequences of operations (e.g., including concurrent and/or sequential operations), will be determined in part by the particular intended application and use environment. Certain features of the illustrated embodiments may have been enlarged or distorted relative to others to facilitate visualization and clear understanding.

### DETAILED DESCRIPTION

### Hardware and Software Environment

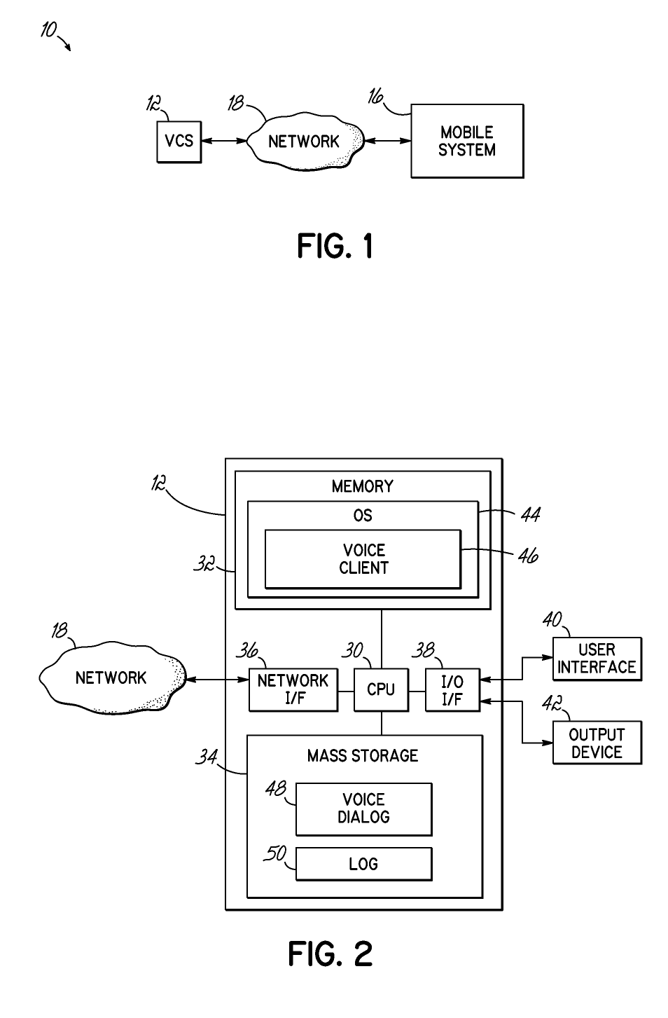

Turning now to the drawings, wherein like numbers denote like parts throughout the drawings, FIG. 1 is a diagrammatic illustration of a voice driven system 10 consistent with embodiments of the invention. The system 10 includes a voice client server 12 (illustrated as, and hereinafter, “VCS” 12), and a mobile system 16. The VCS 12 is configured to convert speech input to machine readable input as well as mediate between interpreted script-based business logic and voice recognition and speech synthesis functions. The mobile system 16 is configured to bundle interpreted programming language script modules and other application resources with an XML-based description of voice dialogs that are used. It will be appreciated that the illustrations of the VCS 12 and mobile system 16 are merely illustrative, and that the functionality of the VCS 12 and/or mobile system 16 may be combined into one component.

FIG. 2 is a diagrammatic illustration of a VCS 12 consistent with embodiments of the invention. In specific embodiments, the VCS 12 is a computer, computing system, computing device, server, disk array, or programmable device such as a multi-user computer, a single-user computer, a handheld computing device, a networked device (including a computer in a cluster configuration), a mobile telecommunications device, a video game console (or other gaming system), etc. As such, the VCS 12 includes at least one central processing unit (CPU) 30 coupled to a memory 32. Each CPU 30 is typically implemented in hardware using circuit logic disposed on one or more physical integrated circuit devices or chips. Each CPU 30 may be one or more microprocessors, micro-controllers, field programmable gate arrays, or ASICs, while memory 32 may include random access memory (RAM), dynamic random access memory (DRAM), static random access memory (SRAM), flash memory, and/or another digital storage medium, and also typically implemented using circuit logic disposed on one or more physical integrated circuit devices, or chips. As such, memory 32 may be considered to include memory storage physically located elsewhere in the VCS 12, e.g., any cache memory in the at least one CPU 30, as well as any storage capacity used as a virtual memory, e.g., as stored on a mass storage device 34, another computing system, a network storage device (e.g., a tape drive), or another network device (e.g., a server) coupled to the VCS 12 through at least one network interface 36 (illustrated as, and hereinafter, “network I/F” 36) by way of the network 18.

The VCS 12 is coupled to at least one peripheral device through an input/output device interface 38 (illustrated as, and hereinafter, “I/O I/F” 38). In particular, the VCS 12 receives data from a user through at least one user interface 40 (including, for example, a keyboard, mouse, a microphone, and/or other user interface) and/or outputs data to the user through at least one output device 42 (including, for example, a display, speakers, a printer, and/or another output device). Moreover, in some embodiments, the I/O I/F 38 communicates with a device that is operative as a user interface 40 and output device 42 in combination, such as a touch screen display (not shown).

The VCS 12 is typically under the control of an operating system 44 and executes or otherwise relies upon various computer software applications, sequences of operations, components, programs, files, objects, modules, etc., consistent with embodiments of the invention. In specific embodiments, the VCS 12 executes or otherwise relies on a voice client application 46 to manage the cooperation of voice dialogs and business logic. The voice client application is referred to hereinafter as a “VoiceArtisan” application 46. The mass storage 34 of the VCS 12 includes a voice dialog data structure 48 and a log data structure 50. The VoiceArtisan application 46 may further log data associated with its operation and store that data in the log data structure 50.

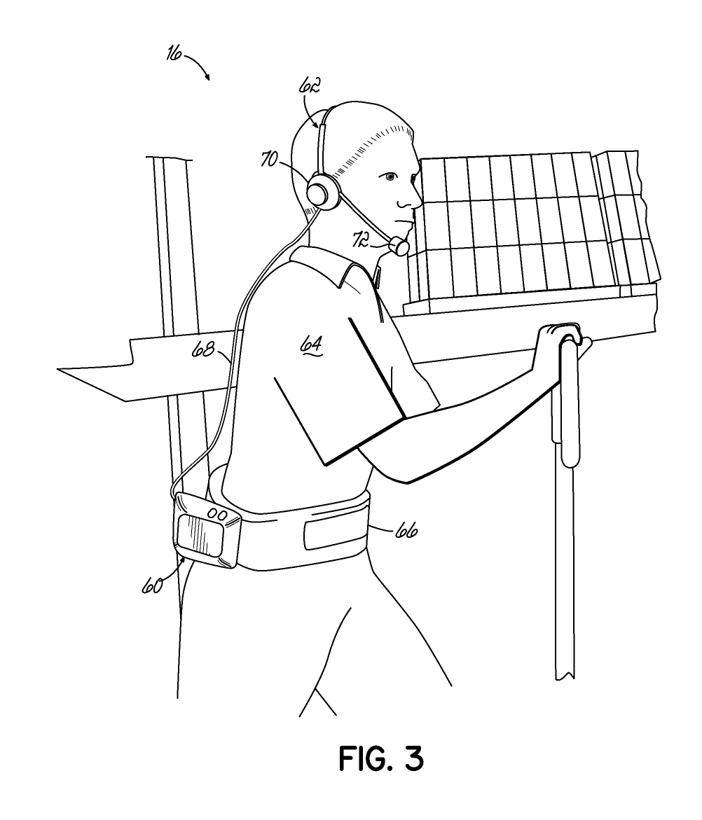

The mobile system 16 is configured to implement a voice dialog flow (e.g., a voice enabled set of steps, such as for a pick-and-place, voice-assisted, or voice-directed operation), capture speech input, and execute business logic. In those embodiments in which the functionality of the VCS 12 and mobile system 16 are separate, the mobile system 16 is also configured to communicate with the VoiceArtisan application 46 across the network 18. FIG. 3 is an illustration of a mobile system 16 consistent with embodiments of the invention. Specifically, the mobile system 16 includes a portable and/or wearable computer or device 60 (hereinafter, “mobile device” 60) and a peripheral device or headset 62 (hereinafter, “headset” 62). As illustrated in FIG. 3, the mobile device 60 is a wearable device worn by a user 64, such as on a belt 66. In alternative embodiments, the mobile device 60 is carried or otherwise transported, such as on the user's forearm, or on a lift truck, harness, or other manner of transportation.

In some embodiments, the user 64 interfaces with the mobile device 60 (and the mobile device 60 interfaces with the user 64) through the headset 62, which is coupled to the mobile device 60 through a cord 68. In alternative embodiments, the headset 62 is a wireless headset and coupled to the mobile device 60 through a wireless signal (not shown). The headset 62 includes a speaker 70 and a microphone 72. The speaker 70 is configured to play audio (e.g., such as speech output associated with a voice dialog to instruct the user 64 to perform an action), while the microphone 72 is configured to capture speech input from the user 64 (e.g., such as for conversion to machine readable input). As such, and in some embodiments, the user 64 interfaces with the mobile device 60 hands-free through the headset 62.

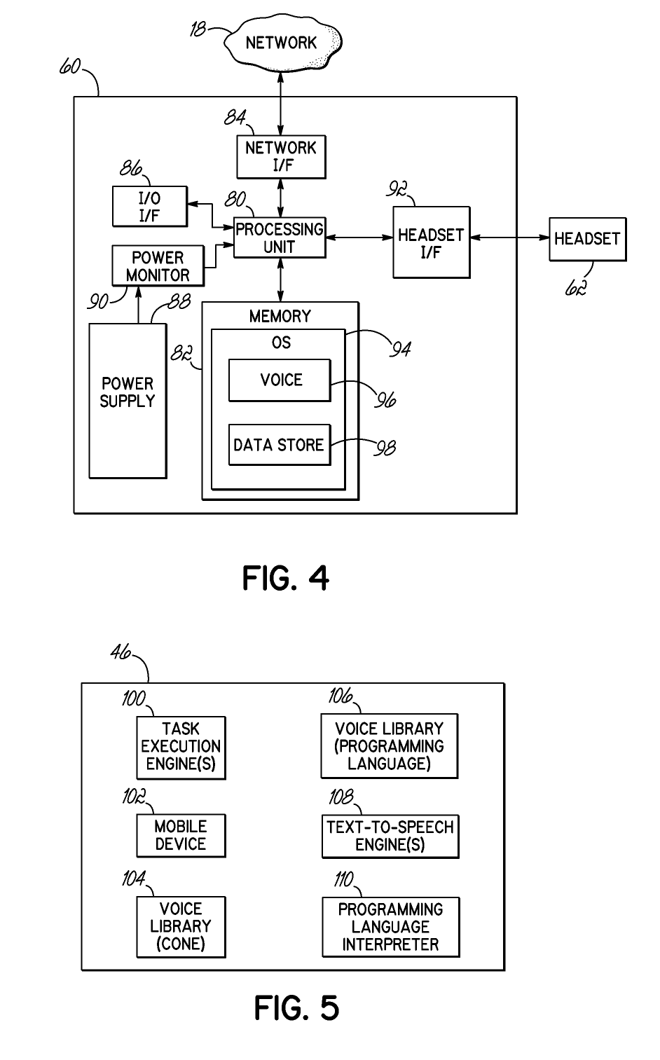

FIG. 4 is a diagrammatic illustration of at least a portion of the components of the mobile device 60 consistent with embodiments of the invention. The mobile device 60 includes at least one processing unit 80 coupled to a memory 82. Each processing unit 80 is typically implemented in hardware using circuit logic disposed in one or more physical integrated circuit devices, or chips. Each processing unit 80 may be one or more microprocessors, micro-controllers, field programmable gate arrays, or ASICs, while memory 82 may include RAM, DRAM, SRAM, flash memory, and/or another digital storage medium, and that is also typically implemented using circuit logic disposed in one or more physical integrated circuit devices, or chips. As such, memory 82 is considered to include memory storage physically located elsewhere in the mobile device 60, e.g., any cache memory in the at least one processing unit 80, as well as any storage capacity used as a virtual memory, e.g., as stored on a mass storage device, a computer, and/or or another device coupled to the mobile device 60, including coupled to the mobile device 60 through at least one network interface 84 (illustrated as, and hereinafter, “network I/F” 84) by way of the network 18. The mobile device 60, in turn, couples to the network 18 through the network I/F 84 with at least one wired and/or wireless connection. In specific embodiments, the mobile device 60 couples to the network 18 through an IEEE 802 standard, and in particular an IEEE 802.11 wireless communications standard as is known in the art.

In some embodiments, the mobile device 60 additionally includes at least one input/output interface 86 (illustrated as, and hereinafter, “I/O I/F” 86) configured to communicate with at least one peripheral other than the headset 62. Such a peripheral may include at least one of one or more training devices (e.g., to coach a new user through training to use the mobile device 60, headset 62, and/or a system to which they are coupled), image scanners, barcode readers, RFID readers, monitors, printers, user interfaces, output devices, and/or other peripherals (none shown). In specific embodiments, the I/O I/F 86 includes at least one peripheral interface, including at least one of one or more serial, universal serial bus (USB), PC Card, VGA, HDMI, DVI, and/or other interfaces (e.g., for example, other computer, communicative, data, audio, and/or visual interfaces) (none shown). The mobile device 60 also includes a power supply 88, such as a battery, rechargeable battery, rectifier, and/or other power source. The mobile device 60 monitors the voltage from the power supply 88 with a power monitoring circuit 90. In some embodiments, and in response to the power monitoring circuit 90 determining that the power from the power supply 88 is insufficient, the mobile device 60 shuts down to prevent potential damage. The mobile device 60 is configured to communicate with the headset 62 through a headset interface 92 (illustrated as, and hereinafter, “headset I/F” 92), which is in turn configured to couple to the headset 62 through the cord 68 and/or wirelessly. In specific embodiments, the mobile device 60 couples to the headset 62 through the BlueTooth® open wireless technology standard that is known in the art.

The mobile device 60 may be under the control and/or otherwise rely upon various software applications, components, programs, files, objects, modules, etc. (hereinafter, “program code”) consistent with embodiments of the invention. This program code may include an operating system 94 (e.g., such as a Windows Embedded Compact operating system as distributed by Microsoft Corporation of Redmond, Wash.) as well as one or more software applications (e.g., configured to operate in an operating system or as “stand-alone” applications). As such, the memory 82 is configured with a voice application 94 to implement dialog flows, execute business logic, and/or communicate with the VoiceArtisan application 96. The memory further includes a data store 98 to store data related to the mobile device 60, headset 62, and/or user 64.

In some embodiments, a suitable mobile device 60 for implementing the present invention is a Talkman® wearable computer available from Vocollect, Inc., of Pittsburgh, Pa. The mobile device 60 is utilized in a voice-enabled system, which uses speech recognition technology for documentation and/or communication. The headset 62 provides hands-free voice communication between the user 64 and the mobile device 60. For example, in one embodiment, the voice application 96 implements a dialog flow, such as for a pick-and-place, voice-assisted, or voice-directed operation. The voice application 96 communicates with the VoiceArtisan application 46 to call voice dialogs. In turn, the voice application 96 can capture speech input for subsequent conversion to a useable digital format (e.g., machine readable input) by the VoiceArtisan application 46.

FIG. 5 is a diagrammatic illustration of a plurality of applications, sequences of operations, components, programs, files, objects, modules, etc., that may be included in the VoiceArtisan application 46 of FIG. 2. In some embodiments, the VoiceArtisan application 46 includes at least one task execution engine 100, a mobile device communication module 102, a core voice library 104, a programming language voice library 106, at least one text-to-speech engine 108, and a programming language interpreter 110. The at least one task execution engine 100 is configured to parse data from the voice application 96 and determine whether to implement a voice dialog. This may include utilizing a text-to-speech engine 108 to convert speech input to machine readable input or passing control back to the voice application 96 to execute business logic. In specific embodiments, the text-to-speech engine 108 may be utilized in conjunction with a voice recognizer (not shown) which is configured to recognize speech input of the user as opposed to noise, speech input of another person, and/or other sounds. The mobile device communication module 102 is configured to format messages to, and parse messages from, the voice application 96.

Referring back to FIG. 5, the VoiceArtisan application also includes a core voice library 104 and a programming language voice library 106. Specifically, the core voice library 104 is configured to store a plurality of voice dialogs to play for the user and/or to store at least one speech input template utilized by the text-to-speech engine 108 to convert speech input of the user into machine readable input (e.g., a “vocabulary”). The programming language voice library 106, on the other hand, is configured to store data used to implement business logic as well as to match requested voice dialogs by the voice application 96 to corresponding voice dialogs in the core voice library 104. Data in the programming language voice library 106 may be used in conjunction with a programming language interpreter 110. The particular programming language may vary depending upon the requirements of the user, but one exemplary programming language may include the Python® programming language developed by the Python Software Foundation of Wolfeboro Falls, N.H.

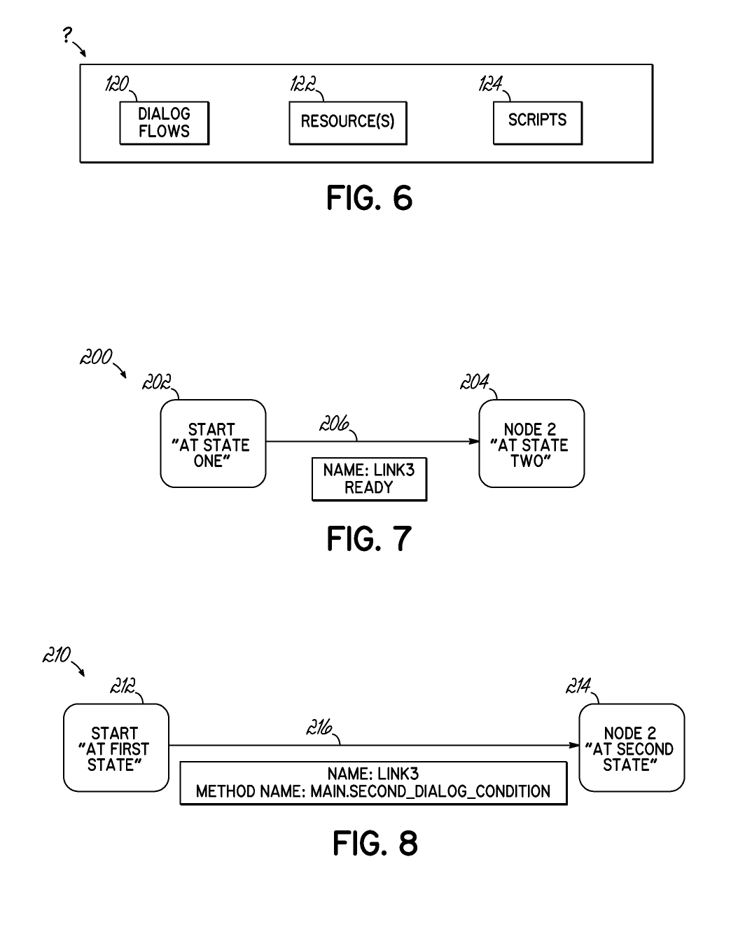

FIG. 6 is a diagrammatic illustration of a plurality of applications, sequences of operations, components, programs, files, objects, modules, etc., that may be included in the voice application 96 of FIG. 4. In some embodiments, the VoiceArtisan application 46 includes at least one dialog flow module 120, at least one resource 122, and at least one programming language script 124. The at least one dialog flow module 120 defines at least one dialog flow for the user. Such dialog flows are typically used in a pick-and-place, voice-assisted, or voice-directed operation. For example, a dialog flow may indicate a voice dialog to be called and/or that a particular sequence of business events (hereinafter, “business logic”) is to be executed. Also for example, and not intending to be limiting, such business logic may include determining whether to perform an action based on the machine readable input, determining whether to perform an action based on input from a user, determining whether to interact with the user or another system, determining whether to perform some action other than the conversion of speech input to machine readable input, as well as other business logic. The at least one resource 122, on the other hand, includes images, sound files, or other data that may be provided to the user. For example, a resource 122 can include a particular image to display, a particular speech output to make, a particular sound tone to make (e.g., to indicate that the voice application 96 is ready for speech input), and/or other data that may be necessary to implement a dialog flow. A programming language script 124, on the other hand, includes a bundle of a particular programming language to execute business logic and is typically developed by a client.

A person having ordinary skill in the art will recognize that the environments illustrated in FIGS. 1-6 are not intended to limit the scope of embodiments of the invention. In particular, the VCS 12 and/or the mobile system 16 may include fewer or additional components, or alternative configurations, consistent with alternative embodiments of the invention. Specifically, the VoiceArtisan application 46 and voice application 96 may not be configured on separate systems, and in alternative embodiments may both be configured on either of the VCS 12 and/or mobile system 16. An alternative mobile system 16 may also be used consistent with embodiments of the invention. For example, the mobile system 16 may include a mobile device 60 and headset 62 that communicate wirelessly. Also for example, the mobile system 16 may include a mobile device 60 and headset 62 that are incorporated with each other in a single, self-contained unit. As such, the single, self contained mobile system may be worn on the head of the user 64.

Thus, a person having skill in the art will recognize that other alternative hardware and/or software environments may be used without departing from the scope of the invention. For example, the voice client 46 and/or client application 96 may be configured with fewer or additional modules, while the mass storage 34 and/or memory 94 may be configured with fewer or additional data structures. Additionally, a person having ordinary skill in the art will appreciate that the VCS 12 and/or mobile system 16 may include more or fewer applications disposed therein. As such, other alternative hardware and software environments may be used without departing from the scope of embodiments of the invention.

Moreover, a person having ordinary skill in the art will appreciate that the terminology used to describe various pieces of data, such as XML, Python, voice dialog, business logic instance, programming language, speech input, and machine readable input are merely used for differentiation purposes and not intended to be limiting.

The routines executed to implement the embodiments of the invention, whether implemented as part of an operating system or a specific application, component, program, object, module or sequence of instructions executed by one or more computing systems will be referred to herein as a “sequence of operations,” a “program product,” or, more simply, “program code.” The program code typically comprises one or more instructions that are resident at various times in various memory and storage devices in a computing system (e.g., the VCS 12 and/or mobile system 16), and that, when read and executed by one or more processors of the computing system, cause that computing system to perform the steps necessary to execute steps, elements, and/or blocks embodying the various aspects of the invention.

While the invention has and hereinafter will be described in the context of fully functioning computing systems, those skilled in the art will appreciate that the various embodiments of the invention are capable of being distributed as a program product in a variety of forms, and that the invention applies equally regardless of the particular type of computer readable media used to actually carry out the distribution. Examples of computer readable media include but are not limited to physical and tangible recordable type media such as volatile and nonvolatile memory devices, floppy and other removable disks, hard disk drives, optical disks (e.g., CD-ROM's, DVD's, etc.), among others.

In addition, various program code described hereinafter may be identified based upon the application or software component within which it is implemented in a specific embodiment of the invention. However, it should be appreciated that any particular program nomenclature that follows is used merely for convenience, and thus the invention should not be limited to use solely in any specific application identified and/or implied by such nomenclature. Furthermore, given the typically endless number of manners in which computer programs may be organized into routines, procedures, methods, modules, objects, and the like, as well as the various manners in which program functionality may be allocated among various software layers that are resident within a typical computer (e.g., operating systems, libraries, APIs, applications, applets, etc.), it should be appreciated that the invention is not limited to the specific organization and allocation of program functionality described herein.

### Software Description and Flows

In general, a dialog flow is created by a user and defines a voice dialog and/or business logic for a voice-enabled operation, such as a pick-and-place, voice-assisted, or voice-directed operation. The user graphically defines the dialog flow on a development environment and further graphically defines the voice dialogs and/or business logic therein. When the dialog flow is built, the development environment generates a Python script for the voice application as well as XML data corresponding to the voice dialogs called in that Python script for the VoiceArtisan application. The VoiceArtisan application, in turn, analyzes the XML data to create voice dialog objects corresponding to the voice dialog's defined in that XML data. When a voice dialog is called by the voice application, the VoiceArtisan application executes a corresponding voice dialog object to perform the function associated with that voice dialog.

In some embodiments, a voice dialog defines a state machine that includes nodes and transitional links that in turn define at least one speech output and/or business logic. Each node represents a state in the state machine while each link is a transition between the states. Without intending to be limiting, types of transitions may include at least one of the following: a default link (in which there is an immediate, unconditional transition); a vocabulary link (in which there is a transition based on recognition of a spoken vocabulary word or phrase); and a conditional link (in which a transition based on the truth of a specific condition). Voice dialogs are connected to the business logic via node or link callback methods.

For example, FIG. 7 is a diagrammatic illustration of a graphical representation of a first voice dialog 200 that shows a plurality of nodes and a link therebetween. Specifically, the graphical representation of the first voice dialog 200 indicates one embodiment of the view that may be seen by a user as they build the voice dialog. The first voice dialog 200 includes a first node 202 that transitions to a second node 204 based upon a link 206. The first voice dialog 200 may called by the voice application consistent with embodiments of the invention. In particular, when the first node 202 is entered, the words “At State One” are spoken. The state machine waits at the vocabulary link 206 for the user to say the word “ready.” When that happens, the state machine transitions to the second node 204 and the words “At State Two” are spoken. At that point, the first voice dialog 200 ends.

In some embodiments, the first node 202 and/or second node 204 may be assigned respective “on entry” functions. As such, the first node 202 may be assigned an “on entry” function called “first_dialog_state_one( )” (e.g., that indicates that there is a voice dialog for the first node 202 of the first voice dialog 200 to specify “At State One” when that node is entered) while the second node 204 may be assigned an “on entry” function called “first_dialog_state_two( )” (e.g., that indicates that there is a voice dialog for the second node 204 of the first voice dialog 200 to specify “At State Two” when that node is entered).

Also for example, FIG. 8 is a diagrammatic illustration of a graphical representation of a second voice dialog 210 that shows a plurality of nodes and a link therebetween. Again, the second voice dialog 210 includes a first node 212 that transitions to a second node 214 based upon a link 216, and may called by a voice application consistent with embodiments of the invention. When the first node 212 is entered, the words “At First State” are spoken. However, the state machine waits at the conditional link 206 indefinitely, until the “second_dialog_condition( )” function returns “True.” When the “second_dialog_condition( )” function returns “True”, the state machine transitions to the second node 204 and the words “At State Two” are spoken. At that point, the second voice dialog 210 ends. It will be appreciated that, similarly to the first voice dialog 200, the first node 212 or second node 214 of the second voice dialog 210 may also be associated with respective “on entry” functions as described above.

Consistent with embodiments of the invention, the first voice dialog 200 and/or second voice dialog 210 may be called by a voice application. In particular, the first and/or second voice dialogs 200 and/or 210 may be called by the “main( )” function of a dialog flow executed by the voice application. Specifically, when a dialog flow is built there are at least two files that are created. The first is the pseudocode for the dialog flow that is executed by the voice application. This psuedocode includes calls to voice dialogs and/or business logic. The second includes XML data that defines the voice dialogs and/or specific business logic associated therewith. The following Code Listing 1 illustrates one embodiment of Python pseudocode for a dialog flow that may be implemented by a voice application that includes a “main( )” function illustrating the use of the first and second voice dialogs 200 and 210, and also illustrating the use of business logic.

CODE LISTING 1: Exemplary “main( )” Function

# This is the driver module for the voice application.
import voice
# This is the driver function for the voice application.
def main( ):

# Add additional application start-up logic here, as desired
# Now run the first_dialog
d = voice.Dialog(‘first_dialog’)
d.run( )
# When the dialog completes, control returns to here
# Do additional business logic here, as desired
# Now run the second dialog
d = voice.Dialog(“second_dialog”)
d.run( )
# When the dialog completes, control returns to here
# Do additional business logic here, as desired
# Program terminates when business logic completed

# This is the function attached to the Start Node in first_dialog
def first_dialog_state_one( ):

# business logic in this function is executed when
# the voice dialog state machine enters the Start node in
# first_dialog
pass

# This is the function attached to Node2 in first_dialog
def first_dialog_state_two( ):

# business logic in this function is executed when
# the voice dialog state machine enters node Node2 in
# first_dialog
pass

# This is the function attached to the conditional link in
# second_dialog
def second_dialog_condition( ):

# business logic in this function is executed when the
# second_dialog attempts to transition from Start node to
# Node2 node via the conditional link.
# The function is called repeatedly until it returns a true
# value, at which point the transition occurs
return True

Thus, as is evident from Code Listing 1, control is handed back and forth between voice dialogs as well as business logic. In particular, Code Listing 1 indicates that the execution begins in the “main( )” function which runs the “first_dialog.” During “first_dialog” execution, there is a call to the “first_dialog_state_one( )” and “first_dialog_state_two( )” functions, which are executed. After the “first_dialog” function terminates the control returns to the “main( )” function to implement business logic, if required. The “main( )” function then runs the “second_dialog” function in which at least one call to a “second_dialog_condition( )” function is executed. After the “second_dialog” function terminates, control again returns to the “main( )” function to implement business logic, if required. The voice application terminates when the “main( )” function completes.

The XML data, in turn, may be used by a task execution engine of a VoiceArtisan application to construct voice dialog objects representing voice dialogs. In particular, the VoiceArtisan application may parse the XML data and build the voice dialog objects in C++ as corollaries to the voice dialogs. When a voice dialog is called by the voice application, the voice dialog is implemented. Specifically, Code Listing 2 illustrates one embodiment of the XML data that includes data about the voice dialogs and/or business logic that are called by Code Listing 1.

CODE LISTING 2: XML Representation for
Voice Dialogs and/or Business Logic

<?xml version=“1.0” encoding=“UTF-8”?>
<voiceApplication>

<start type=“script” value=“main.main” />
<dialog name=“first_dialog”>

<startNode id=“1” />
<node id=“1” name=“Start”>

<prompt value=“At State One” priority=“false” />
<method name=“main.first_dialog_state_one” />

</node>
<linkVocabulary id=“3” name=“Link3” sourceNode=“1”

destinationNode=“2”>

<vocabulary>ready</vocabulary>

</linkVocabulary>
<node id=“2” name=“Node2”>

<prompt value=“At State Two” priority=“false” />
<method name=“main.first_dialog_state_two” />

</node>

</dialog>
<dialog name=“second_dialog”>

<startNode id=“1” />
<node id=“1” name=“Start”>

<prompt value=“At First State” priority=“false” />

</node>
<linkConditional id=“3” name=“Link3” sourceNode=“1”

destinationNode=“2”>

<method name=“main.second_dialog_condition” />

</linkConditional>
<node id=“2” name=“Node2”>

<prompt value=“At Second State” priority=“false” />

</node>

</dialog>

</voiceApplication>

Thus, the XML representation directs the VoiceArtisan application to perform corresponding actions for a voice dialog, whether that be providing speech output, performing speech recognition, or executing other action. After a speech output, the VoiceArtisan may pass back control to the voice application to implement business logic, such as the business logic defined by a transitional link. As such, the interaction of the VoiceArtisan application and the voice application allows for the abstraction of functions across the two. However, direct access to the functionality of the VoiceArtisan application is prevented, maintaining the security thereof.

As detailed above, embodiments of the invention may be used to coordinate voice dialogs and business logic for a voice enabled system, and in particular for a pick and place, voice-assist, and/or voice-directed operation. For example, the dialog flow for a voice application can specify calls for a voice dialog. The voice dialog is recognized by a VoiceArtisan application, which has already created voice dialog objects correlated to the voice objects in the dialog flow. The VoiceArtisan application executes a voice dialog when called. Concurrently, business logic may be implemented by the voice application and/or the VoiceArtisan application based upon information associated with either the voice dialog or the dialog flow.

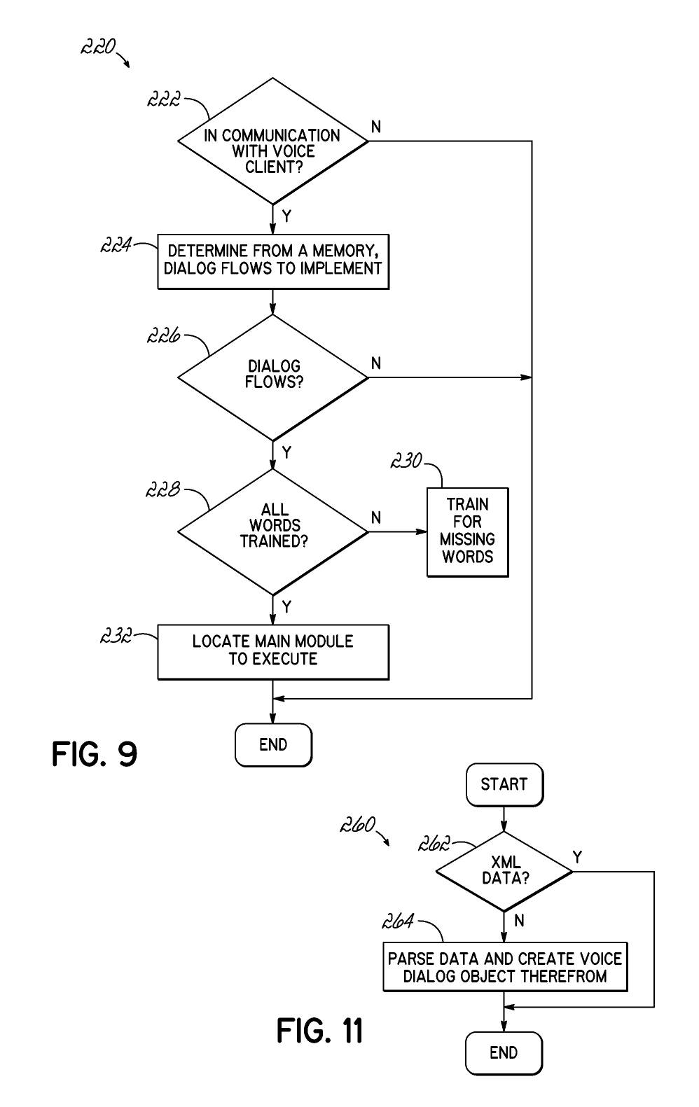

FIG. 9 is a flowchart 220 illustrating a sequence of operations executed by a voice application for configuration thereof consistent with embodiments of the invention. In particular, the voice application determines whether it is in communication with, or otherwise communicate with, a VoiceArtisan application (block 222). Specifically, the voice application initially determines if a VoiceArtisan application is installed and running on the same computing system as that voice application and/or if the VoiceArtisan application is installed and running on a computing system in communication with the voice application. When the voice application is not in communication with the VoiceArtisan application (“No” branch of decision block 222) the sequence of operations may end. Alternatively, and in a block not shown, when the voice application is not in communication with the VoiceArtisan application it may start an instance of a VoiceArtisan application to communicate with, then return to block 222.

When the voice application is in communication with the VoiceArtisan application (“Yes” branch of decision block 222) the voice application determines, from a memory, at least one dialog flow to implement (block 224). When the voice application does not determine any dialog flows to implement (“No” branch of decision block 226) the sequence of operations may end.

In specific embodiments, each dialog flow is defined in XML and includes business logic as well as at least one call to a voice dialog. Additionally, a dialog flow may define particular vocabulary words that are used with that dialog flow in addition to those utilized with a voice dialog. As such, when the voice application determines that there is at least one dialog flow to implement (“Yes” branch of decision block 226) the voice application determines whether all words associated with that dialog flow are available to be converted from speech input to machine readable input or vice-versa (e.g., whether the text-to-speech engine and/or a voice recognizer can convert the particular word to machine readable input and/or convert the particular word to speech output such that the text-to-speech engine and/or voice recognizer have been “trained”) (block 228). When all words for a dialog flow have not been trained (“No” branch of decision block 228) the voice application may capture speech input associated with that word and/or words to train the text-to-speech engine and/or voice recognizer (block 230). When all words for a dialog flow have been trained (“Yes” branch of decision block 228 or block 230) the voice application locates the main module associated with that dialog flow and executes the dialog flow (block 232).

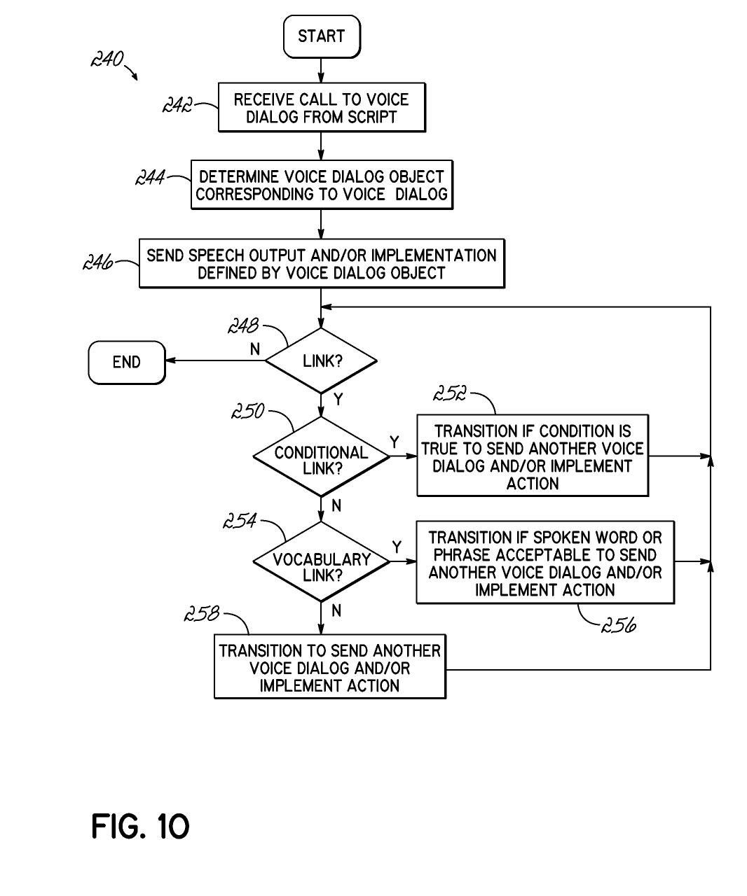

FIG. 10 is a flowchart 240 illustrating a sequence of operations for a VoiceArtisan application to respond to a call for a voice dialog consistent with embodiments of the invention. Specifically, the VoiceArtisan application receives a call to a voice dialog from a script associated with the voice application and may take control of operations from the voice application (block 242). In turn, the VoiceArtisan application determines a voice dialog object corresponding to the called voice dialog (block 244) and executes a first node of the voice dialog to send speech output associated with the requested voice dialog back to the voice application and/or implement an action defined by the voice dialog (e.g., when the voice dialog is not associated with a speech input) (block 246).

In a voice dialog, nodes may be transitioned from one to another with links, which may include default, vocabulary, or conditional links. If there is no link associated with a particular speech output (“No” branch of decision block 248) the sequence of operations ends. However, when there is a link associated with a particular speech output (“Yes” branch of decision block 248) the VoiceArtisan application determines if the link is a conditional link (e.g., an automatic link) (block 250). In a condition link, there is a transition from one node to another when a condition associated with that link is true. Thus, when there is a conditional link (“Yes” branch of decision block 250) the VoiceArtisan application transitions to the next node when a condition associated with that link is true (block 252) and the sequence of operations returns to block 248.

However, when the link is not a conditional link (“No” branch of decision block 250) the VoiceArtisan application determines if the link is a vocabulary link (block 254). When the link is a vocabulary link (“Yes” branch of decision block 254) the VoiceArtisan application transitions to the next node based on the recognition of a spoken vocabulary word or phrase. As such, when the particular vocabulary word or phrase is spoken, the VoiceArtisan application transitions to the next node to send another voice dialog and/or implement business logic (block 256) and returns to block 248. However, when the link is not a vocabulary link (“No” branch of decision block 254) the link may be a default link. In a default link, there is an immediate, unconditional transition from one node to another. As such, the VoiceArtisan application transitions to the next node to send another voice dialog and/or implement business logic (block 258) and returns to block 248.

In some embodiments, control in a dialog flow may be handed off between the voice application and the VoiceArtisan application depending upon the particular operations defined by a dialog flow and/or voice dialog. For example, a vocabulary link of a voice dialog may indicate that a transition occurs when the user says a particular word or phrase. The voice application takes control to capture the speech input of the user and provide it to the VoiceArtisan application for conversion to machine readable input. The VoiceArtisan application converts the speech input to machine readable input, then provides that machine readable input back to the voice application to determine whether the specified word or phrase has been spoken by the user. Thus, the voice application indicates whether to transition to the next node. Also for example, a conditional link may indicate that a transition occurs when a particular barcode is scanned and/or a particular button is pressed. The determination of whether the condition is true, however, is determined by the voice application.

FIG. 11 is a flowchart 260 illustrating a sequence of operations for the VoiceArtisan application to create a voice dialog object consistent with embodiments of the invention. The VoiceArtisan application initially determines whether there is XML data associated with a dialog flow in memory (block 262). When there is XML data associated with a dialog flow (“Yes” branch of decision block 262) the VoiceArtisan application parses that XML data and creates at least one voice dialog object therefreom (block 264). In specific embodiments, the VoiceArtisan application creates C++ corollaries to the voice dialogs that represent the voice dialog data. Thus, when called, the VoiceArtisan application can implement at least some of the operations defined by that voice dialog. When there is no XML data associated with a dialog flow (“No” branch of decision block 262) or after creating at least one voice dialog object (block 264) the sequence of operations may end.

While the present invention has been illustrated by a description of the various embodiments and the examples, and while these embodiments have been described in considerable detail, it is not the intention of the applicants to restrict or in any way limit the scope of the appended claims to such detail. Additional advantages and modifications will readily appear to those skilled in the art. For example, voice dialogs may include more or fewer nodes and transitional links than those illustrated. In particular, a node in a voice dialog may be connected to multiple nodes through multiple transition links (e.g., multiple vocabulary or conditional links). The particular node that is transitioned to may thus be dependent on the particular link (e.g., word, phrase, or condition) used to transition to that node. Moreover, a voice dialog does not necessarily have to include speech output, and may instead include an action (e.g., such as waiting for speech input) or business logic.

Still further, one having ordinary skill in the art will appreciate that the voice application and VoiceArtisan application operate in a cooperative manner. As such, the voice application and VoiceArtisan application may be executed on the same computing system, and in specific embodiments the voice application may be run as a virtual component of the VoiceArtisan application. Thus, the particular nomenclature for the voice application and the VoiceArtisan application is merely for differentiation purposes and is not intended to be limiting. As such, the invention in its broader aspects is therefore not limited to the specific details, apparatuses, and methods shown and described. A person having ordinary skill in the art will appreciate that any of the blocks of the above flowcharts may be deleted, augmented, made to be simultaneous with another, combined, or be otherwise altered in accordance with the principles of the embodiments of the invention. Accordingly, departures may be made from such details without departing from the scope of applicants' general inventive concept.

What is claimed is:

1. A method of cooperatively mediating between voice enabled operations and business logic, comprising:
receiving XML data;
generating at least one object from the XML data; and
in response to determining that the at least one object has been called, implementing an operation defined by a portion of the object.

2. The method of claim 1, wherein implementing the operation includes:
accessing a voice engine to provide a speech output associated with the object to a user.

3. The method of claim 1, further comprising:
implementing the operation in parallel with the execution of at least one sequence of business operations associated with the object.

4. The method of claim 1, wherein the object includes a transition link that defines a transition of the object after implementing the operation.

5. The method of claim 4, wherein the transition link is a default link that indicates a transition from the operation is an immediate and unconditional transition.

6. The method of claim 4, wherein the transition link is a vocabulary link that indicates a transition from the operation is based upon the recognition of at least one word.

7. The method of claim 4, wherein the transition link is a conditional link that indicates a transition from the operation is based upon the truth of a specified condition.

8. The method of claim 4, wherein the transition link indicates a transition from the operation to a second operation.

9. The method of claim 4, wherein the transition link indicates a transition from the operation to a sequence of business operations.

10. The method of claim 1, further comprising:
in response to capturing speech input of the user, converting the speech input to machine readable input.

11. The method of claim 1, wherein the XML data is associated with a dialog flow.

12. An apparatus, comprising:
at least one processing unit;
a memory; and
program code resident in the memory, the program code configured to, when executed by the at least one processing unit, receive XML data, generate at least one object from the XML data, and implement an operation defined by a portion of the object in response to determining that the at least one object has been called.

13. The apparatus of claim 12, wherein the program code is further configured to access a voice engine to provide a speech output associated with the object to a user.

14. The apparatus of claim 12, wherein the program code is further configured to implement the operation in parallel with the execution of at least one sequence of business operations associated with the object.

15. The apparatus of claim 12, wherein the object includes a transition link that defines a transition of the object after implementing the operation.

16. The apparatus of claim 15, wherein the transition link is a default link that indicates a transition from the operation is an immediate and unconditional transition.

17. The apparatus of claim 15, wherein the transition link is a vocabulary link that indicates a transition from the operation is based upon the recognition of at least one word.

18. The apparatus of claim 15, wherein the transition link is a conditional link that indicates a transition from the operation is based upon the truth of a specified condition.

19. The apparatus of claim 15, wherein the transition link indicates a transition from the operation to a second operation.

20. The apparatus of claim 15, wherein the transition link indicates a transition from the operation to a sequence of business operations.

21. The apparatus of claim 12, wherein the program code is further configured to convert speech input of the user to machine readable input in response to capturing the speech input.

22. The apparatus of claim 12, wherein the XML data is associated with a dialog flow.

23. A program product, comprising:
program code configured to, when executed by at least one processing unit, receive XML data, generate at least one object from the XML data, and implement an operation defined by a portion of the object in response to determining that the at least one object has been called; and
a computer readable medium bearing the program code.
